(19) United States
(12) Patent Application Publication
(10) Pub. No.: US 2011/0128727 A1
(43) Pub. Date: Jun. 2, 2011

(54) INTEGRATED SEEBECK DEVICE

(75) Inventors: Jinesh Balakrishna Pillai Kochupurackal, Taman Jurong (IN); Johan Hendrik Klootwijk, Eindhoven (NL)

(73) Assignee: NXP B.V., Eindhoven (NL)

(21) Appl. No.: 13/055,230

(22) PCT Filed: Jul. 22, 2009
(86) PCT No.: PCT/IB09/53177

§ 371 Date: Jan. 21, 2011

(30) Foreign Application Priority Data
Jul. 23, 2008 (EP) 08160952.1

(51) Int. Cl. F21L 4/08; H01L 35/34; H01L 35/30; H01L 35/28; H01M 10/46

(52) U.S. Cl. 362/183; 438/54; 136/205; 136/203; 320/101

(57) ABSTRACT

An integrated device includes a Seebeck device (4) integrated in a substrate (2). A heat-generating device (6) warms up the Seebeck device (4) generating electrical power. The Seebeck device powers a further device which may be a micro-battery (8) likewise integrated in the substrate or a Peltier effect device for cooling another heat-generating device.

### FIELD OF THE INVENTION

The invention relates to an integrated Seebeck effect device and its manufacture and use.

### BACKGROUND OF THE INVENTION

The Seebeck and Peltier effects are related effects. When a pair of semiconductor p-n junctions are connected, with one junction at a higher temperature than the other, electrical current flows in a loop driven by the thermal temperature difference. Devices making use of this effect are known as Seebeck effect devices and they convert thermal temperature differences into electricity.

The Seebeck effect works in reverse, when it is known as the Peltier effect. In a Peltier effect device, current is driven through a pair of p-n junctions and the effect warms one of the junctions up and cools the other. Thus, the Peltier effect device acts as a heat pump.

The size of the effect depends on the materials of the semiconductor as well as other factors such as the area of the junction.

It has been proposed to use the Peltier effect to cool integrated circuits. U.S. Pat. No. 6,639,242 proposes the use of a thermoelectric cooler for use with a Si device. SiGe is used as the semiconductor since it has fairly good properties and is readily integrated with a Si device.

It is also known to generate electrical power from such a device. For example, U.S. Pat. No. 5,419,780 describes the use of a thermoelectric device as a power generator to drive a fan.

### SUMMARY OF THE INVENTION

According to a first aspect of the invention there is provided an integrated device according to claim 1.

The inventors have realized that integrated active devices generate heat which can be used to create electrical power using a Seebeck-effect device. This in turn can be used with other devices, for example to charge a battery for future use or alternatively to operate a Peltier effect device to cool another device.

It might be thought that it would be possible to use the power generated by a Seebeck thermoelectric device under an active device to cool the same active device using a Peltier thermoelectric device. Here, the second law of thermodynamics causes difficulty. The cooling achieved by the Peltier device will cool the device and hence reduce the power generated by the Seebeck device sufficiently that the process will be of low efficiency.

The inventors have realized that integrated devices vary considerably in their sensitivity to heat and their propensity to warm up and generate heat. For example, a resistor may well generate significant amounts of heat in use, but operate successfully at elevated temperatures. Conversely, some semiconductor devices may have properties that are seriously affected by temperature. Accordingly, it is possible to use a Seebeck effect device taking its heat from a device operating at an elevated temperature and use the resulting electricity to operate a Peltier effect device to cool another device which operates at a reduced temperature.

Alternatively, the power from the Seebeck device can be used to charge a rechargeable battery, such as a micro-battery, and the energy stored in this battery may be used for various purposes.

In particular, the active device may be a solid state lighting device and the charge stored in the battery may be used, for example for additional or emergency lighting or to power a controller for the lighting device.

In another aspect, the invention relates to a method of manufacturing the integrated device according to claim 11.

### BRIEF DESCRIPTION OF THE DRAWINGS

For a better understanding of the invention, embodiments will now be described, purely by way of example, with reference to the accompanying drawings, in which:

FIG. 1 shows a first embodiment of an integrated device according to the invention;

FIG. 2 shows a second embodiment of an integrated device according to the invention; and

FIGS. 3 to 7 show steps in manufacturing the Seebeck device of either the first or second embodiments.

The drawings are schematic and not to scale. The same or similar components are given the same reference numbers in different Figures, and the description is not necessarily repeated.

### DETAILED DESCRIPTION OF EMBODIMENTS

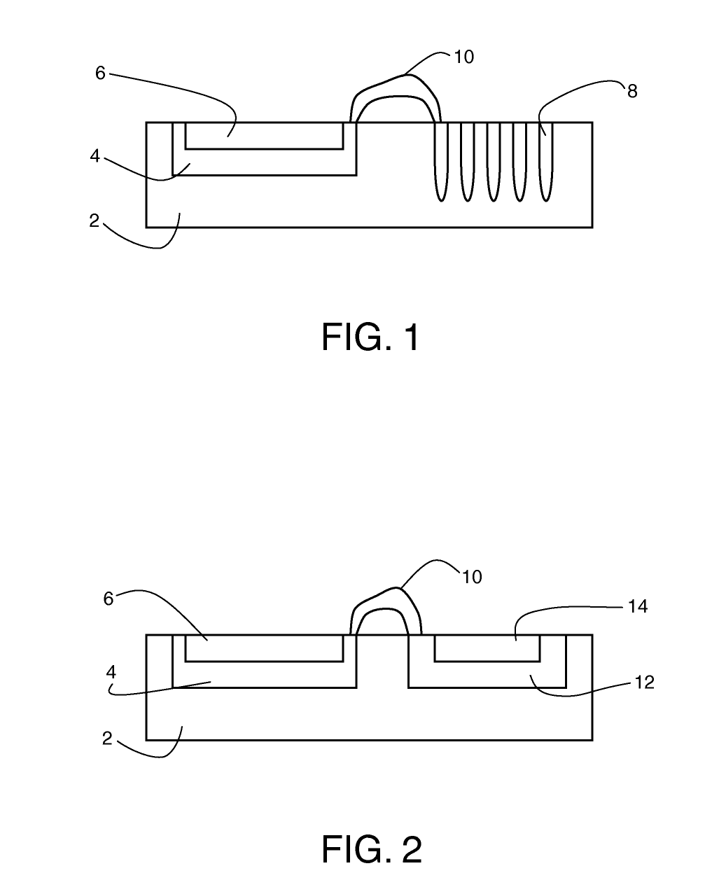

Referring to FIG. 1, a first embodiment of a device includes a silicon substrate 2 with a Seebeck effect device 4 integrated within the substrate 2. Possible structures of this device are described below. A first heat-producing device 6 is mounted on the Seebeck effect device 4.

A micro-battery 8 is integrated into the substrate 2 spaced away from the Seebeck effect device. The micro-battery may be of micrometer or even nanometer scale. Electrical connections 10 connect the Seebeck effect device to the micro-battery 8. These are shown in the drawing schematically away from the substrate but in a typical actual device the connections 10 will be in a metallization layer on the substrate 2.

In use, the heat-producing device 6 produces heat as a result of its normal operation which increases the temperature of the heat-producing device 6 above that of the substrate. This creates a thermal gradient which is converted by the Seebeck effect device 4 into electrical energy, which is used to charge up the micro-battery 8. This stored charge can then be used for other purposes.

FIG. 2 shows another embodiment. Again, a silicon substrate 2 has a Seebeck effect device 4 integrated within it, and a first heat producing device 6 mounted on the Seebeck effect device.

In this case, however, a Peltier effect device 12 is provided in the substrate, and a second heat-producing device 14 mounted on the Peltier effect device.

In use, the heat producing device produces heat as a result of its normal operation which generates electrical energy. In this case, however, the electrical energy is used to drive the Peltier effect device 12 which keeps the second device 14 cool.

Some devices generate more heat than others and other devices are more sensitive to heat than others. By using the heat generated in one device to cool another, it is possible for a relatively heat sensitive second device to be kept cool and with improved functionality.

In particular, the invention is of use with solid state lighting. The inventors have realized that solid state lighting devices develop significant amounts of excess heat and that the use of an integrated Seebeck effect device can effectively capture and reuse at least part of this excess.

The invention does not require the use of any particular form of Seebeck device or Peltier device.

The voltage generated by a Seebeck device is given by

V=(S_{A}−S_{B})) ΔT,

where S_{A} and S_{B} are the Seebeck coefficients of the materials and ΔT the temperature difference.

Using the equation for electrical power P=IV=V²/R this gives the power generated by the Seebeck device, given by

P=S²σ(ΔT²) A/I

where S is the Seebeck coefficient, σ is the electrical conductivity, A the area, ΔT the temperature difference and I the current through the load. The Seebeck coefficient of this equation is strictly the difference between the Seebeck coefficients of the two materials. Accordingly, a device with a large surface area is beneficial.

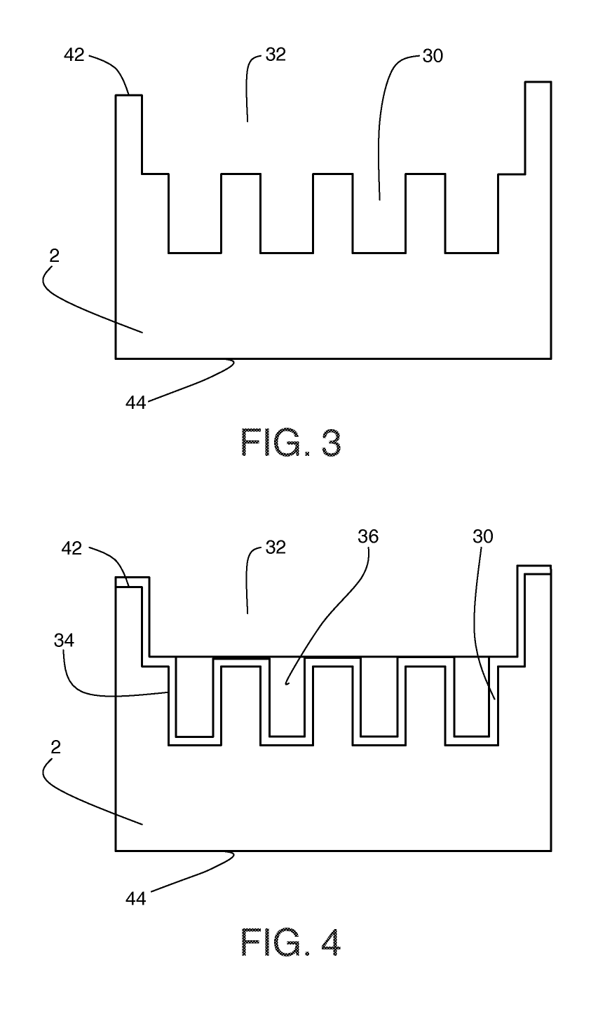

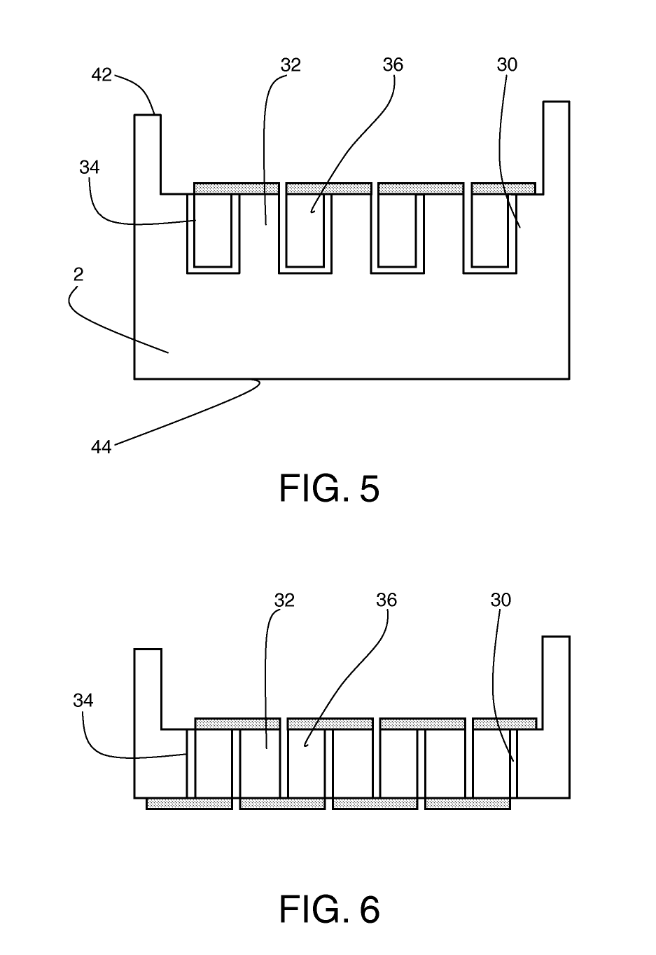

Referring to FIGS. 3 to 7, a method of manufacturing the Seebeck effect device according to FIG. 1 will now be discussed in more detail. FIGS. 3 to 7 just show the region of the Seebeck device 4; the remainder of substrate 2 and the further device or devices 8, 12 are omitted for clarity.

Firstly, deep trenches 30 are etched in a heavily doped silicon wafer 2 extending below a recess 32 where the active device has to be fabricated. The doping is a first conductivity type, in the embodiment p-type.

Next, the trenches are oxidized to form a thin layer of oxide 34 on the surface of the trenches.

Heavily doped polysilicon 36 of a second conductivity type opposite to the first conductivity type is then deposited in the trenches. In the embodiment, the polysilicon is n-type.

Any polysilicon and oxide on the top surface is then removed. In the embodiment, this is done using chemical-mechanical polishing (CMP) but in the alternative an etching process can be used.

At least one top electrode 38 is then deposited and patterned to connect the p-type regions of the substrate and the n-type regions of polysilicon together.

Next, a backside CMP step is used to expose the other ends of the trenches 30. At least one bottom electrode 40 is deposited and patterned on the back of the substrate.

A heat producing device 6 is then formed above the Seebeck array in the recess 32. This may be produced as a separate device on a separate substrate and simply mounted in the recess 32, or the recess may be filled with semiconductor and the heat producing device formed in the semiconductor using conventional processing steps.

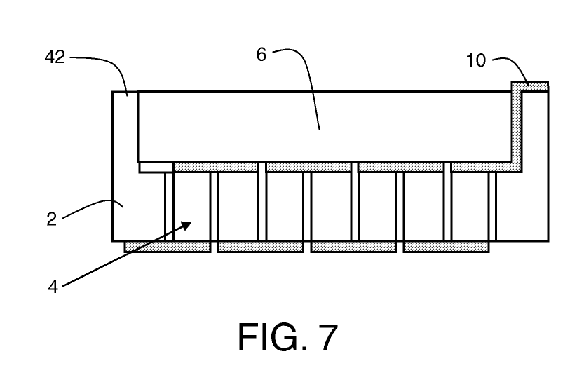

FIG. 7 also shows connections 10 extending from the top electrode.

Note that the large area of the device of FIG. 7 gives a correspondingly large power.

In embodiments using a Peltier effect device 12 the same or similar structure may be used may conveniently be used for that device so that it can be formed in the same processing steps.

In such an embodiment, a single substrate 2 has a readily formed structure 2 with a Seebeck effect device 4 and a Peltier effect device 12, the heat generated by one device 6 mounted on the Seebeck effect device 4 being used to cool another device 14 mounted on the Peltier effect device.

Instead of trenches, holes, pores or mesh structures may be used.

The present integrated device preferably comprises trenches that are from 5-300 μm deep, preferably from 10-200 μm deep, more preferably from 20-100 μm deep, most preferably from 25-50 μm, such as 30 μm, and/or wherein the 3D mesh structure comprises voids with an internal diameter of from 1-100 μm, preferably from 2-50 μm, more preferably from 3-25 μm deep, most preferably from 4-10 μm, such as 5 μm, or combinations thereof.

Although the embodiment mounts the heat producing device 6 in a recess in the first major surface 42, this is optional and the heat-producing device may simply be mounted on the first major surface 42 of the substrate.

To still further improve the power, in an alternative embodiment a material with a larger Seebeck effect than Si may be used instead of Si for either the n-type semiconductor, the p-type semiconductor or both, such as BiTe.

For BiTe, having a thickness of 9.8 μm, the conductivity is 4.10⁻⁵ Ωm, which for an area of 1 mm², a temperature difference of 100° C. and a current of 10⁻⁶A gives 33.86 W.

In a preferred embodiment a combination of p-type and n-type Bismuth Telluride is used, based on their different work function.

Note that the integrated device may be any device, though the invention has particular benefit in the case of integrated lighting devices which generate significant amounts of excess heat. The power generated from the excess heat can be used either to charge a battery to power control circuitry, to cool the control circuitry using a Peltier device or even to provide emergency lighting.

The battery 8 is described above as a micro-battery but the size of the battery is not limited to any particular size.

1. An integrated device, comprising:
a Seebeck device integrated in a substrate, the substrate having opposed first and second major surfaces;
a first device located at the first major surface on the Seebeck device, the first device being a device which generates heat in use;
a further device connected to the Seebeck device and electrically powered by the Seebeck device, the further device being a rechargeable battery or Peltier effect device integrated in the substrate.

2. An integrated device according to claim 1 wherein the substrate is a semiconductor substrate and the Seebeck device comprises a plurality of holes, trenches or a mesh in the substrate under the first device extending towards the second major surface.

3. An integrated device according to claim 2 wherein the substrate is doped to be a first conductivity type, and the Seebeck device further comprises:
an insulating layer in the plurality of holes, trenches or a mesh;
a semiconductor of opposite conductivity type to the first conductivity type in the holes trenches or mesh insulated from the substrate by the insulating layer;
at least one top electrode at the top of the holes, trenches or mesh adjacent to the first device; and
at least one bottom electrode at the opposite end of the holes, trenches or mesh to the top electrode, for generating the electrical power as an electrical potential between the top and bottom electrodes.

4. An integrated device according to claim 3, wherein holes, trenches or mesh extend through the substrate from the first device to a second major surface opposite the first major surface, and the bottom electrode is on the second major surface of the substrate.

5. An integrated device according to claim 1 comprising a recess in the first major surface of the substrate, the heat producing device being mounted in the recess.

6. An integrated device according to claim 1, wherein a further device is a Peltier device, and the integrated device further comprises a second device located on the Peltier device for cooling by the Peltier device.

7. An integrated device according to claim 6, wherein the structure of the Peltier device is the same as the structure of the Seebeck device.

8. An integrated device according to claim 1, wherein the further device is a rechargeable battery connected to the Seebeck device so that it may be recharged by the Seebeck device.

9. An integrated device according to claim 8 wherein the rechargeable battery comprises a plurality of holes extending into the semiconductor substrate.

10. An integrated device according to claim 1 wherein the first device is a solid state lighting device.

11. A method of manufacturing an integrated device, comprising:
forming a Seebeck device integrated in a substrate the substrate having opposed first and second major surfaces;
forming a further device integrated in the substrate connected to the Seebeck device and electrically powered by the Seebeck device; and
locating a first device at the first major surface of the substrate on the Seebeck device, the first device being a device which generates heat in use.

12. A method according to claim 11 wherein the further device is a Peltier effect device, and the Peltier effect device is formed in the same method steps used to form the Seebeck effect device.

13. A method according to claim 11 wherein the further device is a battery.

14. A method according to claim 11 wherein forming the Seebeck device includes:
providing the semiconductor substrate heavily doped to be a first conductivity type,
forming a plurality of holes, trenches or a mesh extending towards the second major surface having a first end towards the first major surface and a second end towards the second major surface;
forming an insulating layer on the sidewalls of the plurality of holes, trenches or mesh;
depositing a semiconductor of opposite conductivity type to the first conductivity type in the holes trenches or mesh insulated from the substrate by the insulating layer;
removing the semiconductor of opposite conductivity type and insulating layer from the first end of the holes, trenches or mesh;
forming at least one top electrode at the first end of the holes, trenches or mesh;
partially removing the substrate from the second major surface towards to expose the second end of the holes, trenches or mesh; and
forming a bottom electrode at the opposite end of the holes, trenches or mesh to the top electrode, for generating the electrical power as an electrical potential between the top and bottom electrodes.

15. Method to harvest thermoelectric power by moving electrons to a battery and thermal energy to a peltier array of an integrated device according to claim 1 respectively.
